(19) United States
(12) Patent Application Publication
(10) Pub. No.: US 2026/0068402 A1
(43) Pub. Date: Mar. 5, 2026

(54) DISPLAY APPARATUS, ELECTRONIC DEVICE INCLUDING THE SAME, AND METHODS OF MANUFACTURING DISPLAY APPARATUS

(71) Applicant: Samsung Display Co., LTD., Yongin-si (KR)

(72) Inventor: Dongha Lee, Yongin-si (KR)

(21) Appl. No.: 19/169,260

(22) Filed: Apr. 3, 2025

(30) Foreign Application Priority Data
Aug. 28, 2024 (KR) 10-2024-0115970

(51) Int. Cl. H10H 29/855; H10H 29/01; H10H 29/37; H10H 29/85; H10H 29/853

(52) U.S. Cl. CPC H10H 29/855; H10H 29/012; H10H 29/0362; H10H 29/0363; H10H 29/37; H10H 29/8517; H10H 29/853

(57) ABSTRACT

A display apparatus includes a substrate, a light-emitting diode disposed on the substrate and including an emission layer, a bank layer disposed on the substrate and defining an opening overlapping the emission layer of the light-emitting diode, a first refractive layer disposed in the opening of the bank layer, and a second refractive layer disposed on the first refractive layer, where the first refractive layer includes a concave top surface and the second refractive layer includes a convex bottom surface and a convex top surface.

This application claims priority to Korean Patent Application No. 10-2024-0115970, filed on Aug. 28, 2024, and all the benefits accruing therefrom under 35 U.S.C. § 119, the content of which in its entirety is herein incorporated by reference.

### BACKGROUND

### 1. Field

Embodiments relate to a display apparatus and a method of manufacturing the same. The display apparatus may include a light-emitting diode and a thin-film transistor.

### 2. Description of the Related Art

A display apparatus visually displays data. The display apparatus may provide an image by light-emitting diodes. The light-emitting diode of the display apparatus may be driven by a thin-film transistor connected to the light-emitting diode. The uses of display apparatuses are becoming more diverse, and various designs to improve the quality of display apparatuses are being attempted. For example, the display apparatus may have lenses that overlap with the light-emitting diodes to achieve various effects, such as increasing frontal luminance and limiting left and right viewing angles.

### SUMMARY

To achieve various effects, the display apparatus may be provided with lenses of different shapes. For example, the display apparatus may include a concave lens and a convex lens overlapping the light-emitting diode. The concave lens and the convex lens may overlap each other. For example, the convex lens may be disposed on the concave lens. When forming each lens, various variables such as the shape of the lens, the refractive index of the lens, and the focal length of the lens need to be controlled. Embodiments include a method of forming a lens while facilitating control over the various variables described above.

Additional features will be set forth in part in the description which follows and, in part, will be apparent from the description, or may be learned by practice of the presented embodiments of the disclosure.

In an embodiment of the disclosure, a display apparatus includes a substrate, a light-emitting diode disposed on the substrate and including an emission layer, a bank layer disposed on the substrate and defining an opening overlapping the emission layer of the light-emitting diode, a first refractive layer disposed in the opening of the bank layer, and a second refractive layer disposed on the first refractive layer, where the first refractive layer has a concave top surface and the second refractive layer includes a convex bottom surface and a convex top surface.

In an embodiment, the second refractive layer may be disposed in the opening of the bank layer.

In an embodiment, the second refractive layer may cover at least a portion of a top surface of the bank layer.

In an embodiment, the emission layer of the light-emitting diode may be disposed in the opening of the bank layer.

In an embodiment, the light-emitting diode may include a pixel electrode under the emission layer and an opposite electrode disposed on the emission layer, and the first refractive layer may be disposed on the opposite electrode.

In an embodiment, the display apparatus may further include an encapsulation layer covering an entirety of the light-emitting diode, and the bank layer, the first refractive layer, and the second refractive layer may be disposed on the encapsulation layer.

In an embodiment, the display apparatus may further include a color filter disposed in the opening of the bank layer, and the first refractive layer may be disposed on the color filter.

In an embodiment, a refractive index of the first refractive layer may be smaller than a refractive index of the second refractive layer.

In an embodiment, the concave top surface of the first refractive layer and the convex bottom surface of the second refractive layer may match each other.

In an embodiment of the disclosure, an electronic device includes a display apparatus and a housing receiving the display apparatus, where the display apparatus includes a substrate, a light-emitting diode disposed on the substrate and including an emission layer, a bank layer disposed on the substrate and defining an opening overlapping the emission layer of the light-emitting diode, a first refractive layer disposed in the opening of the bank layer, and a second refractive layer disposed on the first refractive layer, where the first refractive layer has a concave top surface and the second refractive layer has a convex bottom surface and a convex top surface.

In an embodiment of the disclosure, a method of manufacturing a display apparatus includes disposing a bank layer defining an opening on a substrate, disposing a first refractive layer with a concave top surface in the opening of the bank layer, and disposing a second refractive layer with a convex bottom surface and a convex top surface on the first refractive layer, where disposing the first refractive layer includes disposing a first solution in the opening of the bank layer, drying the first solution, and hardening a dried first solution.

In an embodiment, drying the first solution may be performed in a vapor pressure of a solvent of the first solution.

In an embodiment, disposing the second refractive layer may include disposing a second solution on the first refractive layer and hardening the second solution.

In an embodiment, disposing the second solution may be performed after hardening the first solution.

In an embodiment, the method of manufacturing a display apparatus may further include disposing a pixel electrode under the bank layer to overlap the opening of the bank layer, disposing an emission layer in the opening of the bank layer, and disposing an opposite electrode on the bank layer.

In an embodiment, the first refractive layer may be disposed on the opposite electrode.

In an embodiment, the method of manufacturing a display apparatus may further include disposing on the substrate a light-emitting diode including a pixel electrode, an emission layer, and an opposite electrode, and disposing an encapsulation layer to cover an entirety of the light-emitting diode, where the bank layer may be disposed on the encapsulation layer.

In an embodiment, the method of manufacturing a display apparatus may further include disposing a color filter in the opening of the bank layer, and the first refractive layer may be disposed on the color filter.

In an embodiment, a refractive index of the first refractive layer may be smaller than a refractive index of the second refractive layer.

In an embodiment, the concave top surface of the first refractive layer and the convex bottom surface of the second refractive layer may match each other.

### BRIEF DESCRIPTION OF THE DRAWINGS

The above and other features and advantages of illustrative embodiments of the disclosure will be more apparent from the following description taken in conjunction with the accompanying drawings, in which:

FIG. 1 is a schematic plan view of an embodiment of an electronic device;

FIG. 2 is a schematic cross-sectional view of an embodiment of a display apparatus;

FIG. 3 is a schematic cross-sectional view of an embodiment of a display apparatus;

FIGS. 4A, 4B, 4C, 4D, 4E, and 4F are schematic cross-sectional views of an embodiment of each operation of a method of manufacturing a display apparatus;

FIG. 5 is a schematic cross-sectional view of an embodiment of a display apparatus;

FIG. 6 is a schematic cross-sectional view of an embodiment of a display apparatus; and

FIGS. 7A, 7B, 7C, 7D, 7E, and 7F are schematic cross-sectional views of an embodiment of each operation of a method of manufacturing a display apparatus.

### DETAILED DESCRIPTION

As the disclosure allows for various changes and numerous embodiments, illustrative embodiments will be shown in the drawings and described in the detailed description. Effects and features of the disclosure, and methods for achieving them will be clarified with reference to embodiments described below in detail with reference to the drawings. However, the disclosure is not limited to the following embodiments and may be embodied in various forms.

Hereinafter, embodiments will be described in detail with reference to the accompanying drawings, where the same or corresponding elements are denoted by the same reference numerals throughout and a repeated description thereof is omitted.

Although the terms “first,” “second,” etc., may be used to describe various elements, these elements should not be limited by these terms. These terms are only used to distinguish one element from another.

As used herein, the singular forms “a,” “an,” and “the” are intended to include the plural forms as well, unless the context clearly indicates otherwise.

It will be understood that the terms “comprising,” “including,” and “having” are intended to indicate the existence of the features or elements described in the specification, and are not intended to preclude the possibility that one or more other features or elements may exist or may be added.

It will be further understood that, when a layer, region, or component is referred to as being “on” another layer, region, or component, it may be directly on the other layer, region, or component, or may be indirectly on the other layer, region, or component with intervening layers, regions, or components therebetween.

Sizes of components in the drawings may be exaggerated or reduced for convenience of explanation. For example, because sizes and thicknesses of components in the drawings are arbitrarily shown for convenience of explanation, the disclosure is not limited thereto.

When an illustrative embodiment may be implemented differently, a specific operating order may be different from the described order. For example, two consecutively described operations may be performed substantially at the same time or may be performed in an order opposite to the described order.

“A and/or B” is used herein to select only A, select only B, or select both A and B. “At least one of A or B”is used to select only A, select only B, or select both A and B.

In the following embodiments, when a layer, a region, a component, etc. are connected to each other, the layer, the region, and the components may be directly connected to each other and/or the layer, the region, and the components may be indirectly connected to each other with other layers, and other regions and other components may be interposed between the layer, the region, and the components. For example, when a layer, a region, a component, etc. are electrically connected to each other in the specification, the layer, the region, the component, etc. may be directly electrically connected to each other, and/or the layer, the region, the component, etc. may be indirectly electrically connected to each other with other layers, and other regions and other components may be interposed between the layer, the region, and the components.

The x axis, the y axis, and the z axis are not limited to three axes on a Cartesian coordinate system, and may be interpreted in a broader sense including the same. For example, the x axis, the y axis, and the z axis may be perpendicular to each other, but may refer to different axes that are not perpendicular to each other.

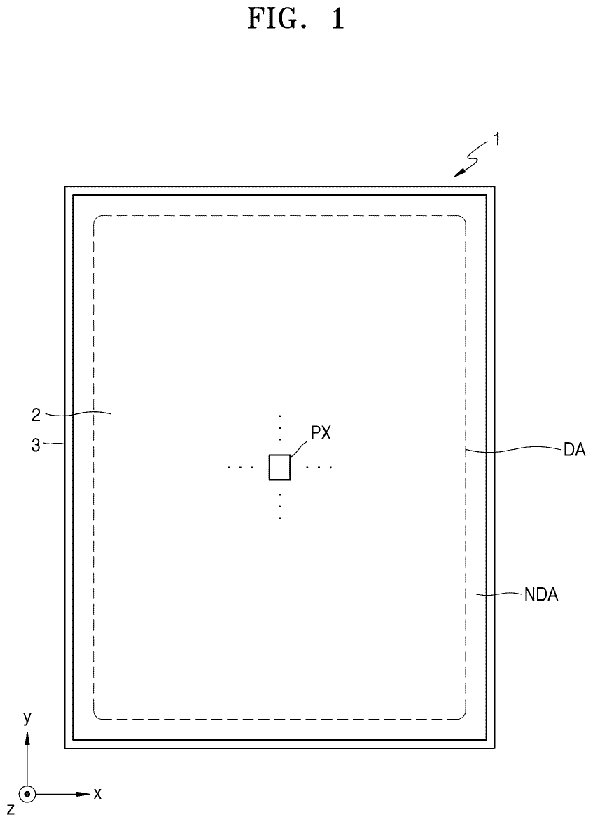

FIG. 1 is a schematic plan view of an embodiment of an electronic device.

Referring to FIG. 1, an electronic device 1 may include a display apparatus 2 and a housing 3. In an embodiment, the display apparatus 2 may be received in the housing 3.

The electronic device 1 may include various products such as a television, a laptop, a monitor, a billboard, an Internet of Things (“IoT”) device, etc. as well as portable electronic devices such as a mobile phone, a smart phone, a tablet personal computer, a mobile communication terminal, an electronic notebook, an electronic book, a portable multimedia player (“PMP”), a navigation device, an ultra mobile PC (“UMPC”), and so on. The electronic device 1 in an embodiment may include wearable devices such as a smart watch, a watch phone, a glasses-type display, and a head mounted display (“HMD”). The electronic device 1 in an embodiment may include a dashboard of a car, a center information display (“CID”) disposed on a center fascia or a dashboard of a car, a mirror display replacing a side mirror of a car, and a display screen disposed on a rear surface of a front seat as entertainment for backseat passengers in a vehicle. The display apparatus 2 may be included in the electronic device 1 as a component for displaying video or still images in various embodiments of the aforementioned electronic device 1.

The display apparatus 2 may include a display area DA and a non-display area NDA outside the display area DA. The display apparatus 2 may display images through sub-pixels PX disposed in the display area DA. The non-display area NDA may be an area outside the display area DA, may not display images, and may surround an entirety of the display area DA. Drivers for supplying electrical signals or power to the display area DA may be disposed in the non-display area NDA. Pads to which electronic elements or printed circuit boards may be electrically connected may be disposed in the non-display area NDA.

Although FIG. 1 shows the display area DA having a quadrangular shape, e.g., rectangular shape with a length in an x-direction that is less than a length in a y-direction, in an embodiment, the display area DA may have a quadrangular shape, e.g., rectangular shape with a length in the y-direction that is less than a length in the x-direction. Although FIG. 1 shows the display area DA to be substantially a rectangle, in an embodiment, the display area DA may have various shapes such as an N-gon (where N is a natural number greater than or equal to 3, N≠4), a circle, or an ellipse. Although FIG. 1 shows the corners of the display area DA to be of a shape including a corner where a straight line and another straight line meet, in an embodiment, the display area DA may be a polygon with rounded corners.

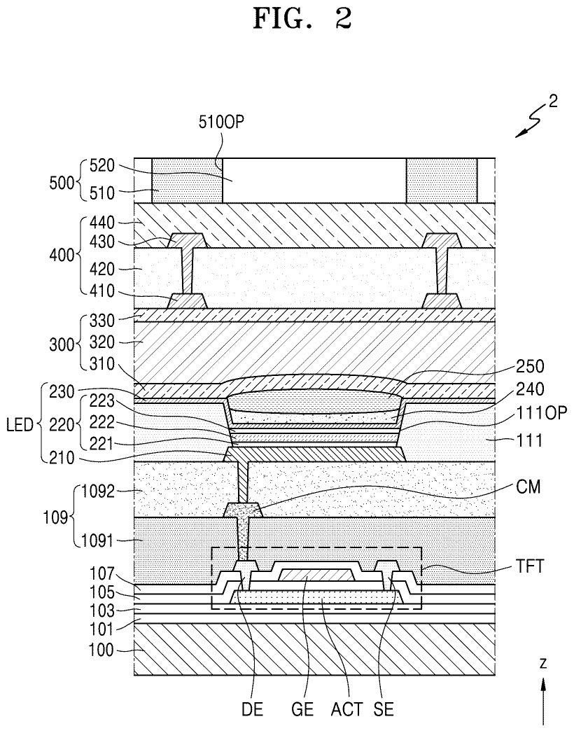

FIG. 2 is a schematic cross-sectional view of an embodiment of a display apparatus 2.

Referring to FIG. 2, a light-emitting diode LED including an emission layer 222 may be disposed on the substrate 100 as a display element. The light-emitting diode LED may be electrically connected to a thin-film transistor TFT.

The substrate 100 may include glass or polymer resin. In an embodiment, the polymer resin may include polyethersulfone, polyacrylate, polyetherimide, polyethylene naphthalate, polyethylene terephthalate, polyphenylene sulfide, polyarylate, polyimide, polycarbonate, cellulose acetate propionate, or the like. The substrate 100 including the polymer resin may have flexible, rollable, or bendable properties. The substrate 100 may have a single-layer structure or a multi-layer structure. When the substrate 100 has a multi-layer structure, the substrate 100 may include a layer including polymer resin and a layer including an inorganic insulating material.

A barrier layer 101 may be disposed on the substrate 100. The barrier layer 101 may serve to flatten and protect the top surface of the substrate 100. The barrier layer 101 may include at least one inorganic insulating material, such as silicon oxide (SiOₓ), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO₂). The barrier layer 101 may have a single-layer structure or a multi-layer structure. In an embodiment, the barrier layer 101 may be integrated into the substrate 100. In this case, the substrate 100 may have the aforementioned multi-layer structure, and the barrier layer 101 may be part of the aforementioned layer including an inorganic insulating material.

A buffer layer 103 may be disposed on the barrier layer 101. The buffer layer 103 may serve to protect the top surface of the barrier layer 101 (or the substrate 100). The buffer layer 103 may include at least one inorganic insulating material, such as silicon oxide (SiOₓ), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO₂). The buffer layer 103 may have a single-layer structure or a multi-layer structure.

The thin-film transistor TFT may be disposed on the buffer layer 103. The thin-film transistor TFT may include an active layer ACT, a gate electrode GE, a source electrode SE, and a drain electrode DE. The thin-film transistor TFT may be connected to the light-emitting diode LED to drive the light-emitting diode LED.

The active layer ACT may be disposed on the buffer layer 103, and may include a drain region overlapping the drain electrode DE, a source region overlapping the source electrode SE, and a channel region disposed between the drain region and the source region. The drain region and the source region may be doped with impurities (i.e., dopants).

The gate insulating layer 105 may be disposed on the active layer ACT. The gate insulating layer 105 may include an inorganic insulating material. The gate insulating layer 105 may include at least one inorganic insulating material, such as silicon oxide (SiOₓ), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO₂). The gate insulating layer 105 may have a single-layer structure or a multi-layer structure.

The gate electrode GE may be disposed on the gate insulating layer 105. The gate electrode GE may overlap the active layer ACT. In an embodiment, the gate electrode GE may overlap the channel region of the active layer ACT, for example. The gate electrode GE may include at least one conductive material from among aluminum (Al), platinum (Pt), palladium (Pd), silver (Ag), magnesium (Mg), gold (Au), nickel (Ni), neodymium (Nd), iridium (Ir), chrome (Cr), calcium (Ca), molybdenum (Mo), titanium (Ti), tungsten (W), and/or copper (Cu). The gate electrode GE may have a single-layer structure or a multilayer structure.

An inter-insulating layer 107 may be disposed on the gate electrode GE. The inter-insulating layer 107 may include an inorganic insulating material. The inter-insulating layer 107 may include at least one inorganic insulating material, such as silicon oxide (SiOₓ), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO₂). The inter-insulating layer 107 may have a single-layer structure or a multi-layer structure.

The gate insulating layer 105 and the inter-insulating layer 107 may include a contact hole overlapping the source region of the active layer ACT, and a contact hole overlapping the drain region of the active layer ACT. The source electrode SE and the drain electrode DE may be disposed on the inter-insulating layer 107. The source electrode SE may overlap the source region of the active layer ACT and the drain electrode DE may overlap the drain region of the active layer ACT. The source electrode SE and the drain electrode DE may each be connected to the active layer ACT through contact holes defined in the gate insulating layer 105 and the inter-insulating layer 107. In an embodiment, the source electrode SE may be connected to the source region of the active layer ACT, and the drain electrode DE may be connected to the drain region of the active layer ACT, for example.

An organic insulating layer 109 may be disposed on the inter-insulating layer 107. In an embodiment, the organic insulating layer 109 may include a first organic insulating layer 1091 and a second organic insulating layer 1092. The first organic insulating layer 1091 and the second organic insulating layer 1092 may be sequentially disposed on the inter-insulating layer 107. Each of the first organic insulating layer 1091 and the second organic insulating layer 1092 may define an opening overlapping the drain electrode DE. A contact metal CM may be disposed on the first organic insulating layer 1091. The contact metal CM may be connected to the drain electrode DE through a contact hole defined in the first organic insulating layer 1091. An opening defined in the second organic insulating layer 1092 overlapping the drain electrode DE may overlap the contact metal CM.

The contact metal CM may include aluminum (Al), copper (Cu), and/or titanium (Ti). The contact metal CM may have a single-layer structure or a multi-layer structure.

The first organic insulating layer 1091 and the second organic insulating layer 1092 may include general-purpose polymers, polymer derivatives having a phenol-based group, acryl-based polymers, imide-based polymers, aryl ether-based polymers, amide-based polymers, fluorine-based polymers, p-xylene-based polymers, or vinyl alcohol-based polymers. Each of the first organic insulating layer 1091 and the second organic insulating layer 1092 may have a single-layer structure or a multi-layer structure.

A pixel electrode 210 may be disposed on the second organic insulating layer 1092. The pixel electrode 210 may be connected to the contact metal CM through the opening defined in the second organic insulating layer 1092. Accordingly, the pixel electrode 210 may be connected to the thin-film transistor TFT through the contact metal CM and the drain electrode DE and may receive a voltage.

The pixel electrode 210 may include a conductive oxide such as indium tin oxide (“ITO”), indium zinc oxide (“IZO”), zinc oxide (ZnO), indium oxide (In₂O₃), indium gallium oxide (“IGO”), or aluminum zinc oxide (“AZO”). The pixel electrode 210 may include a reflective film including silver (Ag), magnesium (Mg), aluminum (Al), platinum (Pt), palladium (Pd), gold (Au), nickel (Ni), neodymium (Nd), iridium (Ir), chrome (Cr), or any combinations thereof. However, a configuration and material of the pixel electrode 210 are not limited thereto, and may be variously modified.

A pixel-defining layer 111 may be disposed on the second organic insulating layer 1092. The pixel-defining layer 111 may cover an edge of the pixel electrode 210. In other words, the pixel-defining layer 111 may be opened to expose a central portion of the pixel electrode 210. In an embodiment, an opening 111OP overlapping the central portion of the pixel electrode 210 may be defined in the pixel-defining layer 111, for example. The opening 111OP of the pixel-defining layer 111 may overlap the emission layer 222. Accordingly, a size and shape of an emission area of the light-emitting diode LED may be defined by the opening 111OP of the pixel-defining layer 111. In this embodiment, the pixel-defining layer 111 may be understood as a bank layer.

An intermediate layer 220 may be disposed on the pixel electrode 210. The intermediate layer 220 may include a first common layer 221, a second common layer 223 and the emission layer 222 disposed in the opening 111OP of the pixel-defining layer 111 In an embodiment, the emission layer 222 may be disposed in the opening 111OP of the pixel-defining layer 111 on the first common layer 221, and the second common layer 223 may be disposed on the first common layer 221 to cover the emission layer 222. In other words, the emission layer 222 may be disposed in the opening 111OP of the pixel-defining layer 111, and may be between the first common layer 221 and the second common layer 223.

The emission layer 222 may include an organic emission layer including a low-molecular weight or polymer material. The first common layer 221 may include an electron transport layer (“ETL”) and/or an electron injection layer (“EIL”). The second common layer 223 may include a hole transport layer (“HTL”) and/or a hole injection layer (“HIL”). In an embodiment, the first common layer 221 or the second common layer 223 may be omitted. In an embodiment, the first common layer 221 and the second common layer 223 may be swapped.

An opposite electrode 230 may be disposed on the intermediate layer 220. In an embodiment, the opposite electrode 230 may be disposed on the second common layer 223, for example. The opposite electrode 230 may cover an entirety of the intermediate layer 220. The opposite electrode 230 may include a conductive material with a relatively low work function. The opposite electrode 230 may include a (semi-)transparent layer including silver (Ag), magnesium (Mg), aluminum (Al), platinum (Pt), palladium (Pd), gold (Au), nickel (Ni), neodymium (Nd), iridium (Ir), chrome (Cr), or any alloys thereof. In an alternative embodiment, the opposite electrode 230 may further include a layer including ITO, IZO, ZnO, or In₂O₃, on the (semi-)transparent layer including the materials described above.

A portion of the opposite electrode 230 may be disposed in the opening 111OP of the pixel-defining layer 111. A first refractive layer 240 and a second refractive layer 250 may be disposed on the opposite electrode 230. The second refractive layer 250 may be disposed on the first refractive layer 240.

At least a portion (e.g., all) of the first refractive layer 240 may be disposed in the opening 111OP of the pixel-defining layer 111. The first refractive layer 240 may have a concave top surface. In an embodiment, the first refractive layer 240 may include a top surface that is curved in an opposite direction of the z-axis direction, for example. In other words, the first refractive layer 240 may include a top surface that is indented in the opposite direction of the z-axis direction.

The first refractive layer 240 may include a polymeric material. In an embodiment, the first refractive layer 240 may include at least one of an amine-based polymeric material, an epoxy-based polymeric material, or a vinyl-based polymeric material, for example. However, this is merely one of embodiments and the disclosure is not limited thereto.

At least a portion (e.g., all) of the second refractive layer 250 may be disposed in the opening 111OP of the pixel-defining layer 111, for example. The second refractive layer 250 may have a convex bottom surface and a convex top surface. In an embodiment, the second refractive layer 250 may include a top surface that is curved in the z-axis direction and a bottom surface that is curved in the opposite direction of the z-axis direction, for example. In other words, the second refractive layer 250 may include a top surface and a bottom surface that each protrude along the z-axis.

FIG. 2 shows an embodiment in which a portion of the second refractive layer 250 convexly protrudes beyond the top surface of the pixel-defining layer 111 and the top surface of the opposite electrode 230. However, this merely exemplary and in another embodiment, the second refractive layer 250 may have a convex top surface, but the convex top surface of the second refractive layer 250 may not protrude beyond the top surface of the pixel-defining layer 111 or the top surface of the opposite electrode 230.

FIG. 2 shows an embodiment in which an edge of the second refractive layer 250 touches (or coincides with) an edge of the opposite electrode 230 that bends into the opening 111OP of the pixel-defining layer 111. However, this is merely exemplary and the edge of the second refractive layer 250 may touch any portion of the opposite electrode 230.

The second refractive layer 250 may include a polymeric material. In an embodiment, the second refractive layer 250 may include an acrylate-based polymeric material, for example. However, this is merely one of embodiments and the disclosure is not limited thereto.

A refractive index of the first refractive layer 240 and a refractive index of the second refractive layer 250 may be different from each other. In an embodiment, the refractive index of the first refractive layer 240 may be smaller than the refractive index of the second refractive layer 250, for example. That is, the refractive index of the second refractive layer 250 may be larger than the refractive index of the first refractive layer 240. In this case, the first refractive layer 240 may include a relatively low refractive index material and the second refractive layer 250 may include a relatively high refractive index material.

The concave top surface of the first refractive layer 240 and the convex bottom surface of the second refractive layer 250 may match with each other. In an embodiment, the curvature of the concave top surface of the first refractive layer 240 and the curvature of the convex bottom surface of the second refractive layer 250 may be the same, for example. Accordingly, when the second refractive layer 250 is disposed on the first refractive layer 240, there is no space between the first refractive layer 240 and the second refractive layer 250. In an embodiment, the curvature of the convex top surface of the second refractive layer 250 and the curvature of the convex bottom surface of the second refractive layer 250 may be the same.

An encapsulation layer 300 may be disposed on the first refractive layer 240 and the second refractive layer 250. The encapsulation layer 300 may cover an entirety of the second refractive layer 250. The encapsulation layer 300 may cover an entirety of the opposite electrode 230.

The encapsulation layer 300 may include at least one inorganic layer and at least one organic layer. In an embodiment, the encapsulation layer 300 may include a first inorganic encapsulation layer 310, a second inorganic encapsulation layer 330, and an organic encapsulation layer 320 between the first inorganic encapsulation layer 310 and the second inorganic encapsulation layer 330. The first inorganic encapsulation layer 310 and/or the second inorganic encapsulation layer 330 may include at least one inorganic insulating material, such as silicon oxide (SiOₓ), silicon nitride (SiNₓ), silicon oxynitride (SiON), aluminum oxide (Al₂O3), titanium oxide (TiO₂), tantalum oxide (Ta₂O₅), hafnium oxide (HfO₂), or zinc oxide (ZnO₂). The organic encapsulation layer 320 may include a polymeric material. The polymeric material may include silicone-based resins, acrylic resins, epoxy-based resins, polyimides, and polyethylene.

A touch layer 400 may be disposed on the encapsulation layer 300. The touch layer 400 detects an external input, e.g., a touch of an object such as a finger or stylus pen, so that the display apparatus 2 may obtain coordinate information corresponding to a touch position. The touch layer 400 may include a touch electrode and trace lines connected to the touch electrode. The touch layer 400 may detect an external input by a mutual cap method or self cap method.

In an embodiment, the touch layer 400 may be formed directly on the encapsulation layer 300. In an alternative embodiment, the touch layer 400 may be separately formed, and then may be adhered to the encapsulation layer 300 through an adhesive layer such as an optically clear adhesive (“OCA”).

The touch layer 400 may include a first touch electrode 410, a first touch insulating layer 420, a second touch electrode 430, and a second touch insulating layer 440. The first touch electrode 410 may be disposed on the encapsulation layer 300. In an embodiment, the first touch electrode 410 may be disposed on the second inorganic encapsulation layer 330, for example. The first touch insulating layer 420, the second touch electrode 430, and the second touch insulating layer 440 may be sequentially disposed on the first touch electrode 410. The first touch insulating layer 420 and/or the second touch insulating layer 440 may include an inorganic insulating material and/or an organic insulating material. The first touch electrode 410 and the second touch electrode 430 may not overlap the emission area of the light-emitting diode LED. In an embodiment, the first touch electrode 410 and the second touch electrode 430 may not overlap the pixel electrode 210 or the opening 111OP of the pixel-defining layer 111, for example.

In some embodiments, an insulating film may be further disposed between the first touch electrode 410 and the second inorganic encapsulation layer 330. The insulating film may include at least one inorganic insulating material selected from among silicon oxide (SiOₓ), silicon nitride (SiNₓ), and silicon oxinitride (SiON).

An optical layer 500 may be disposed on the touch layer 400. The optical layer 500 may include a light-blocking layer 510 and/or a color filter 520. The light-blocking layer 510 may overlap the first touch electrode 410 and the second touch electrode 430 of the touch layer 400. The light-blocking layer 510 may include light-blocking material. In an embodiment, the light-blocking layer 510 may include polyimide with black dye, for example. Accordingly, the light-blocking layer 510 may be visible as an opaque color, for example black. By covering the first touch electrode 410 and the second touch electrode 430 under the light-blocking layer 510, the light-blocking layer 510 may stop the first touch electrode 410 and/or second touch electrode 430 being visible to the user due to reflection of exterior light on the first touch electrode 410 and/or the second touch electrode 430.

The light-blocking layer 510 may define an opening 510OP overlapping the emission area of the light-emitting diode LED. Accordingly, the light-blocking layer 510 may allow light emitted from the light-emitting diode LED to pass through. The light-blocking layer 510 may overlap the pixel-defining layer 111. The opening 510OP of the light-blocking layer 510 may overlap the opening 111OP of the pixel-defining layer 111.

The color filter 520 may be disposed in the opening 510OP of the light-blocking layer 510. The color filter 520 may transmit light in a predetermined wavelength range. In an embodiment, the color filter 520 may transmit light with a similar wavelength range (i.e., color) to a wavelength range (i.e., color) of the light emitted from the light-emitting diode LED, for example. Although the color filter 520 fills up an entirety of the opening 510OP of the light-blocking layer 510 in the illustrated embodiment, the disclosure is not necessarily limited thereto.

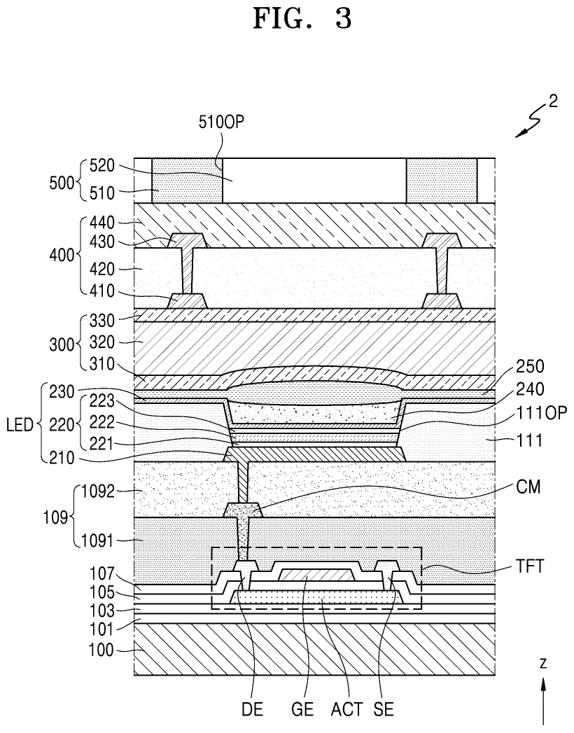

FIG. 3 is a schematic cross-sectional view of an embodiment of a display apparatus 2.

Regarding the embodiment shown in FIG. 3, because the difference between the embodiments shown in FIGS. 2 and 3 is in the shape of the second refractive layer 250, redundant descriptions are omitted. In this embodiment, the pixel-defining layer 111 may be understood as the bank layer.

Referring to FIG. 3, the second refractive layer 250 may cover at least a portion (e.g., an entirety) of a top surface of the opposite electrode 230 or a top surface of the pixel-defining layer 111. A portion of the second refractive layer 250 may be disposed in the opening 111OP of the pixel-defining layer 111. Another portion of the second refractive layer 250 may extend on the top surface of the opposite electrode 230 overlapping the top surface of the pixel-defining layer 111. Although FIG. 3 shows an embodiment in which the second refractive layer 250 covers an entirety of the top surface of the opposite electrode 230 and the pixel-defining layer 111, this is merely one of embodiments and the disclosure is not necessarily limited thereto. In another embodiment, the second refractive layer 250 may cover only a portion of the top surface of the opposite electrode 230 and the pixel-defining layer 111.

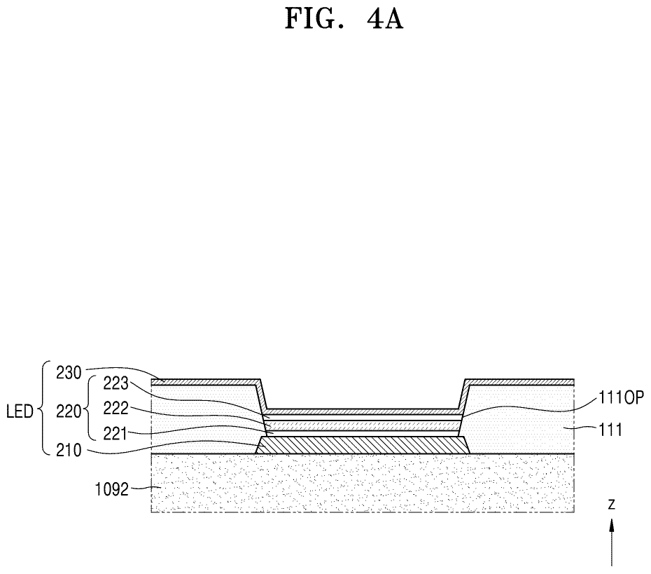

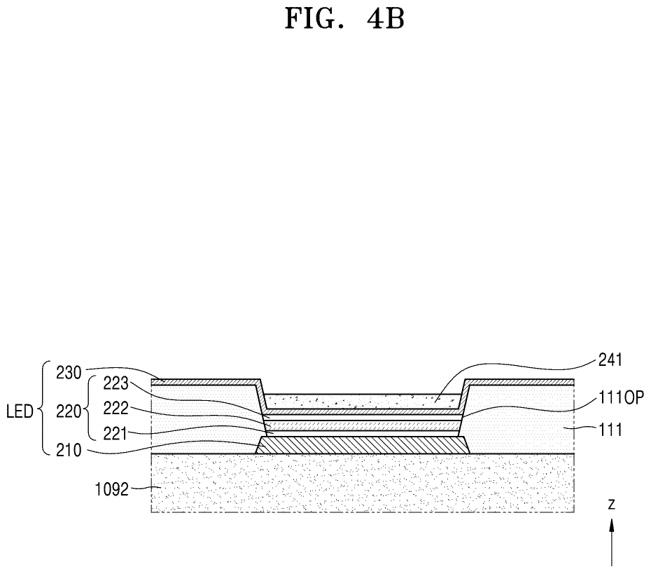

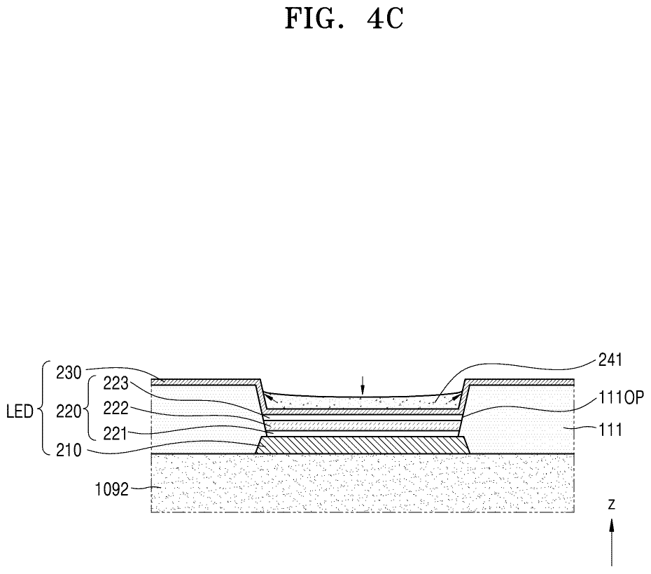

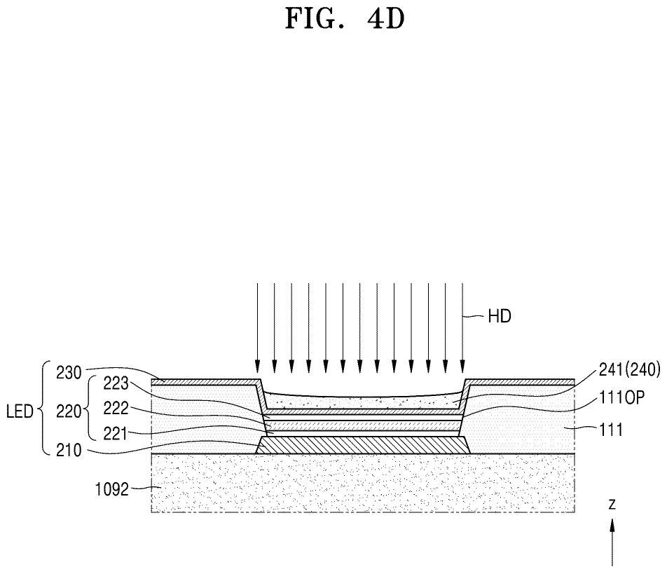

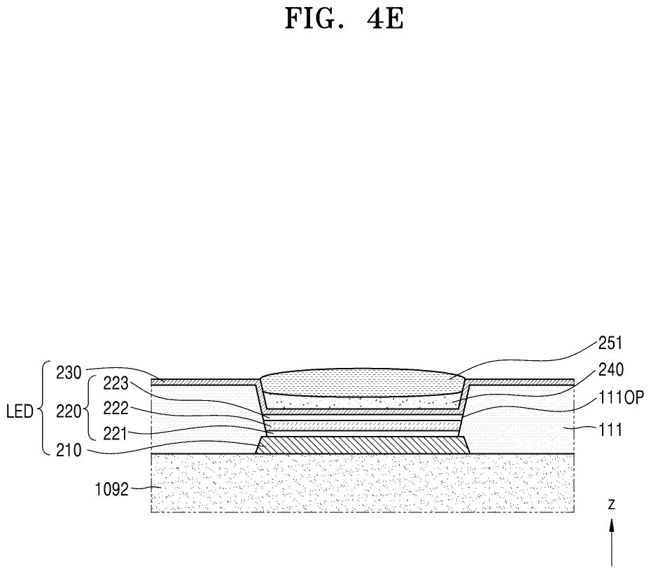

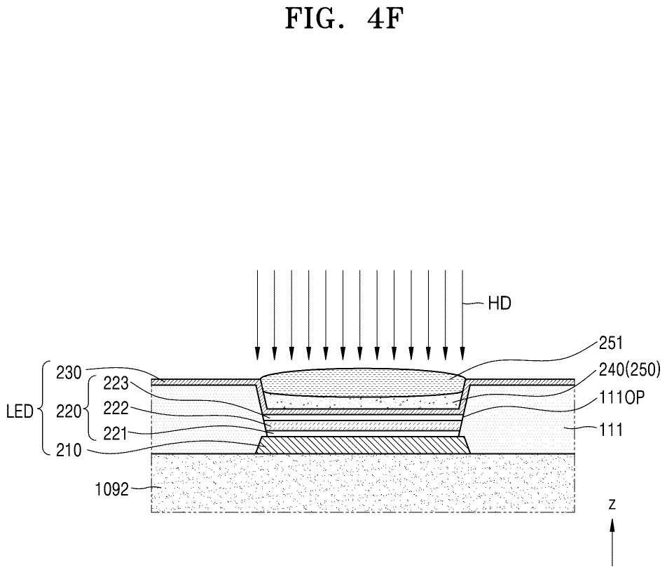

FIGS. 4A to 4F are schematic cross-sectional views of an embodiment of each operation of a method of manufacturing a display apparatus.

FIGS. 4A to 4F show the process of forming the first refractive layer 240 and the second refractive layer 250 of FIG. 2. While the disclosure focuses on description of implementing the embodiment shown in FIG. 2, it will be apparent to those of ordinary skill in the art that the method described herein may also be applied to implementing the embodiment shown in FIG. 3. In this embodiment described with reference to FIGS. 4A to 4F, the pixel-defining layer 111 may be understood as the bank layer.

Referring to FIG. 4A, the pixel electrode 210, the pixel-defining layer 111, the first common layer 221, the emission layer 222, the second common layer 223, and the opposite electrode 230 may be sequentially disposed on the second organic insulating layer 1092. The structure of the pixel electrode 210, the pixel-defining layer 111, the first common layer 221, the emission layer 222, the second common layer 223, and the opposite electrode 230 disposed on the second organic insulating layer 1092 may be the same as described above with reference to FIG. 2. In an embodiment, the pixel-defining layer 111 may define an opening 111OP overlapping the pixel electrode 210 and the emission layer 222, for example.

Referring to FIG. 4B, a first solution 241 may be disposed in the opening 111OP of the pixel-defining layer 111. The first solution 241 may be disposed on the opposite electrode 230. In an embodiment, the first solution 241 may include (e.g., as a solute) polymeric material. In an embodiment, the first solution 241 may include (e.g., as a solute) at least one of polymeric materials such as amine-based, epoxy-based, or vinyl-based polymeric materials, for example. In an embodiment, the first solution 241 may be disposed via an inkjet operation.

Referring to FIG. 4C, the first solution 241 may be dried. In an embodiment, the first solution 241 may be dried in a drying chamber. In an embodiment, a pressure within the drying chamber may the same with a vapor pressure of the solvent of the first solution 241. In other words, in an embodiment, the first solution 241 may be dried in a vapor pressure environment of the first solution 241.

By drying the first solution 241, a coffee-ring effect may be induced. The solutes of the first solution 241 (e.g., the polymeric material described above) may gather at the peripheral side of the first solution 241. In an embodiment, the solutes of the first solution 241 may gather by a side of the pixel-defining layer 111 which defines the opening 111OP, for example. As the solutes of the first solution 241 gather at the peripheral side, a central side of the first solution 241 may have relatively less solutes, and the central side of the first solution 241 may cave in. Accordingly, the first solution 241 may be formed to have a larger thickness at the peripheral side than the central side. As a result, the concave shape of the top surface of the first refractive layer 240 (refer to FIG. 2) described above may be implemented.

Referring to FIG. 4D, the first solution 241 may be hardened. Hardening may be performed by delivering a hardening agent HD to the first solution 241. The hardening agent HD may be heat, or light with a predetermined wavelength (e.g., ultraviolet). The shape of the first solution 241 implemented by drying as described above, i.e., the concave shape of the top surface, may be fixed via hardening. The dried and hardened first solution 241 may be understood as the first refractive layer 240.

The first refractive layer 240 may be disposed in the opening 111OP of the pixel-defining layer 111 via the operations described above with reference to FIGS. 4B to 4D. As a result of the above-described operations, the first refractive layer 240 may have a concave top surface.

Referring to FIG. 4E, a second solution 251 may be disposed on the first refractive layer 240. In an embodiment, the second solution 251 may be disposed after hardening the first solution 241 (i.e., after forming the first refractive layer 240). In an embodiment, the second solution 251 may include (e.g., as a solute) polymeric material. In an embodiment, the second solution 251 may include (e.g., as a solute) an acrylate-based polymeric material, for example. In an embodiment, the second solution 251 may be disposed in the opening 111OP of the pixel-defining layer 111 and on the first refractive layer 240 via an inkjet operation. In an embodiment, the second solution 251 may include a material with a larger refractive index than a refractive index of the material of the first solution 241. Accordingly, the refractive index of the first solution 241 may be smaller than the refractive index of the second solution 251, and the refractive index of the first refractive layer 240 may be smaller than the refractive index of the second refractive layer 250.

Because the first refractive layer 240 is in a hardened state, the shape of the first refractive layer 240 (e.g., the concave shape) may be maintained without deformation when the second solution 251 is disposed on the first refractive layer 240. Because the second solution 251 may have fluidity, the second solution 251 may be disposed on the first refractive layer 240 so that the bottom surface of the second solution 251 fits the shape of the top surface of the first refractive layer 240. In other words, the bottom surface of the second solution 251 may fit the top surface of the first refractive layer 240. When a sufficient amount of the second solution 251 is disposed, the top surface of the second solution 251 may protrude over the top surface of the opposite electrode 230 (i.e., a partial portion of the second solution 251 may protrude over the top surface of the opposite electrode 230), and may have a convex shape depending on properties (e.g., contact angle, surface tension) of the second solution 251. In other words, the top surface of the second solution 251 may have a convex shape by itself. In other words, the top surface of the second solution 251 may have a convex shape without any treatment. The convex shape of the top surface of the second solution 251 obtained by itself and the convex shape of the bottom surface of the second solution 251 obtained by the shape of the top surface of the first refractive layer 240 may be the same, or may be different.

Referring to FIG. 4F, the second solution 251 may be hardened. Hardening may be performed by delivering a hardening agent HD to the second solution 251. The hardening agent HD may be heat, or light with a predetermined wavelength(e.g., ultraviolet). The hardened second solution 251 may be understood as the second refractive layer 250. The convex shape of the top surface and the convex shape of the bottom surface of the second solution 251 implemented by the above-described factors may also be implemented in the second refractive layer 250. Accordingly, the concave top surface of the first refractive layer 240 and the convex bottom surface of the second refractive layer 250 may match with each other.

The second refractive layer 250 may be disposed on the first refractive layer 240 via the operations described above with reference to FIGS. 4E and 4F. The concave shape of the first refractive layer 240 and the convex shape of the second refractive layer 250 may be easily formed the operations described above. In other words, the concave lens and the convex lens disposed on the light-emitting diode LED may easily be formed by the processes described above.

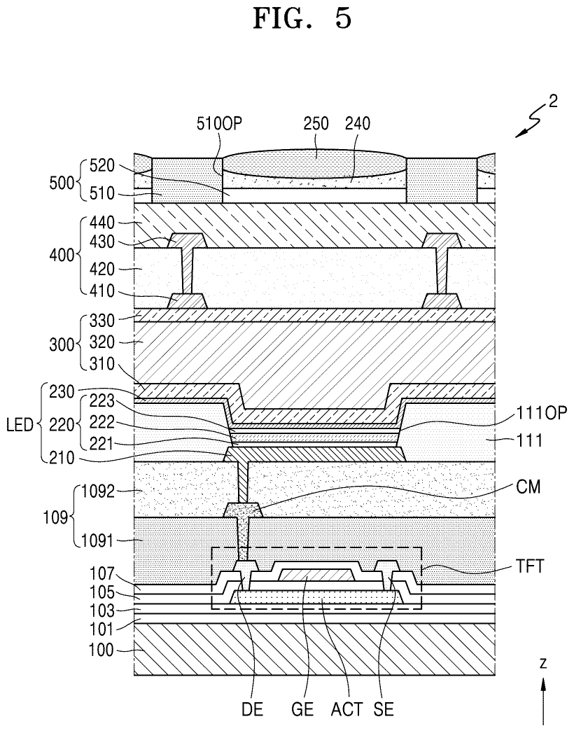

FIG. 5 is a schematic cross-sectional view of an embodiment of a display apparatus 2.

The embodiment shown in FIG. 5 is substantially the same as the embodiment shown in FIG. 2 other than the features of the first refractive layer 240 and the second refractive layer 250, thus the difference will be described below.

Referring to FIG. 5, in the illustrated embodiment, the light-blocking layer 510 may be understood as the bank layer. The color filter 520 may fill a partial portion of the opening 510OP of the light-blocking layer 510.

The first refractive layer 240 and the second refractive layer 250 may be disposed above the encapsulation layer 300 and the touch layer 400. In an embodiment, the first refractive layer 240 and the second refractive layer 250 may be disposed within the optical layer 500, for example. At least a portion (e.g., an entirety) of the first refractive layer 240 may be disposed in the opening 510OP of the light-blocking layer 510. The first refractive layer 240 may be disposed on the color filter 520. At least a portion (e.g., an entirety) of the second refractive layer 250 may be disposed in the opening 510OP of the light-blocking layer 510. The second refractive layer 250 may be disposed on the first refractive layer 240.

FIG. 5 shows an embodiment in which a portion of the second refractive layer 250 convexly protrudes beyond the top surface of the light-blocking layer 510. However, this merely exemplary and in another embodiment, the second refractive layer 250 may have a convex top surface, but the convex top surface of the second refractive layer 250 may not protrude beyond the top surface of the light-blocking layer 510.

FIG. 5 shows an embodiment in which an edge of the second refractive layer 250 touches (or coincides with) an edge of the light-blocking layer 510 that defines the opening 510OP of the light-blocking layer 510. However, this is merely exemplary and the edge of the second refractive layer 250 may touch any portion of the light-blocking layer 510.

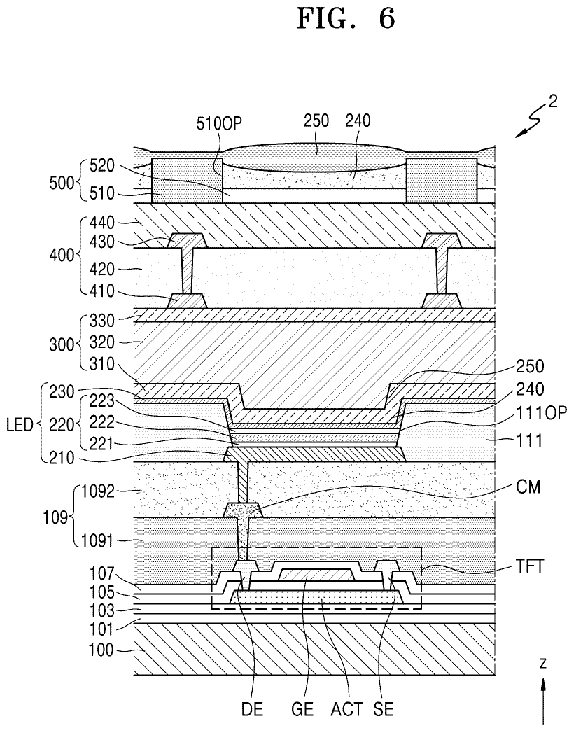

FIG. 6 is a schematic cross-sectional view of an embodiment of a display apparatus 2.

Regarding the embodiment shown in FIG. 6, because the difference between the embodiments shown in FIGS. 5 and 6 is in the shape of the second refractive layer 250, redundant descriptions are omitted. In the illustrated embodiment, the light-blocking layer 510 may be understood as the bank layer.

Referring to FIG. 6, the second refractive layer 250 may cover at least a portion (e.g., an entirety) of a top surface of the light-blocking layer 510. A portion of the second refractive layer 250 may be disposed in the opening 510OP of the light-blocking layer 510. Another portion of the second refractive layer 250 may extend on the top surface of the light-blocking layer 510. Although FIG. 6 shows an embodiment in which the second refractive layer 250 covers an entirety of the top surface of the light-blocking layer 510, this is merely one of embodiments and the disclosure is not necessarily limited thereto. In another embodiment, the second refractive layer 250 may cover only a portion of the top surface of the light-blocking layer 510.

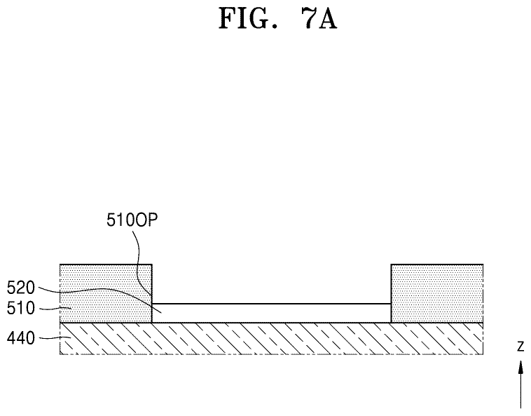

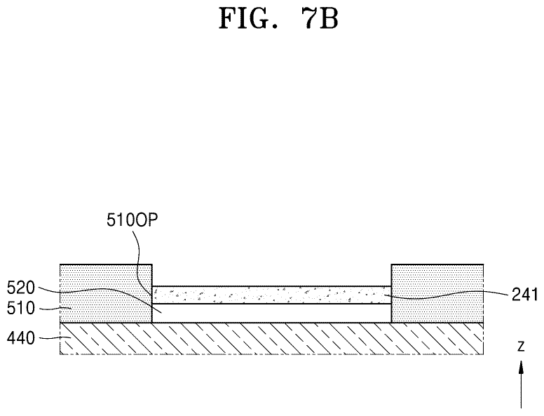

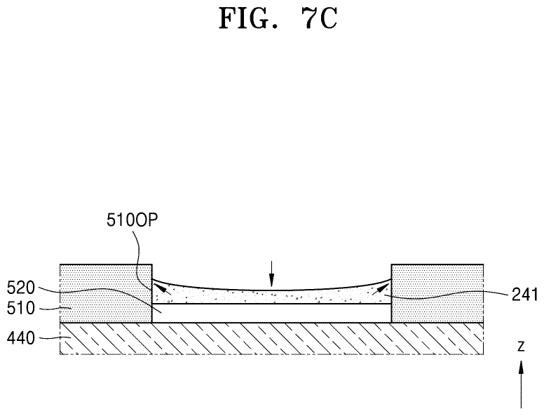

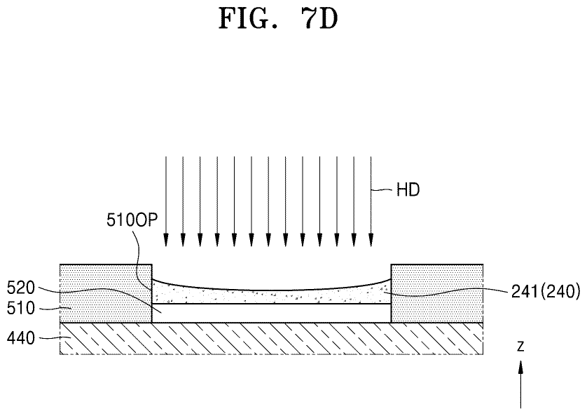

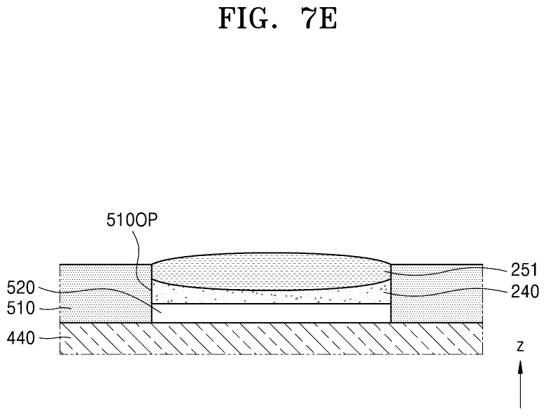

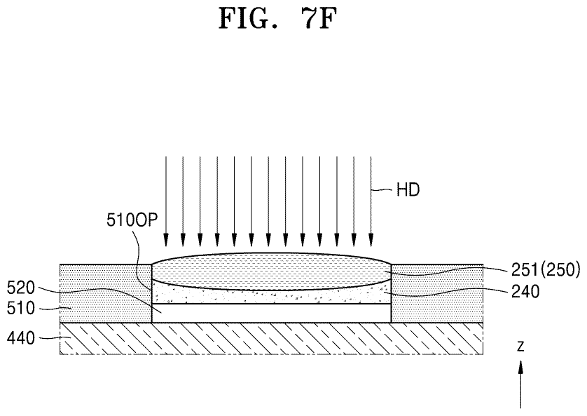

FIGS. 7A to 7F are schematic cross-sectional views of an embodiment of each operation of a method of manufacturing a display apparatus.

FIGS. 7A to 7F show the process of forming the first refractive layer 240 and the second refractive layer 250 of FIG. 5. While the disclosure focuses on description of implementing the embodiment shown in FIG. 5, it will be apparent to those of ordinary skill in the art that the method described herein may also be applied to implementing the embodiment shown in FIG. 6. In this embodiment described with reference to FIGS. 7A to 7F, the light-blocking layer 510 may be understood as the bank layer.

The operations described with reference to FIGS. 7A to 7F may be substantially the same in other respects when compared to the operations described with reference to FIGS. 4A to 4F, differing only in the locations where the first solution 241, second solution 251, first refractive layer 240, and second refractive layer 250 are disposed.

Referring to FIG. 7A, the light-emitting diode LED (FIG. 5), the encapsulation layer 300 (FIG. 5), and the touch layer 400 (FIG. 5) may be formed. The light-blocking layer 510 may define an opening 510OP, and the color filter 520 may be disposed in the opening 510OP of the light-blocking layer 510. The color filter 520 may fill a partial portion the opening 510OP of the light-blocking layer 510.

Referring to FIG. 7B, the first solution 241 may be disposed in the opening 510OP of the light-blocking layer 510. The first solution 241 may be disposed on the color filter 520. Other features of the operation may be substantially the same as features of the embodiment described with reference to FIG. 4B.

Referring to FIG. 7C, the first solution 241 may be dried, and features of the operation may be substantially the same as features of the embodiment described with reference to FIG. 4C.

Referring to FIG. 7D, the first solution 241 may be hardened, and features of the operation may be substantially the same as features of the embodiment described with reference to FIG. 4D.

The first refractive layer 240 may be disposed in the opening 510OP of the light-blocking layer 510 via the operations described above with reference to FIGS. 7B to 7D, and the first refractive layer 240 may have a concave top surface.

Referring to FIG. 7E, a second solution 251 may be disposed on the first refractive layer 240. The second solution 251 may be disposed in the opening 510OP of the light-blocking layer 510 and on the first refractive layer 240. Other features of the operation may be substantially the same as features of the embodiment described with reference to FIG. 4E.

Referring to FIG. 7F, the second solution 251 may be hardened, and features of the operation may be substantially the same as features of the embodiment described with reference to FIG. 4F.

The second refractive layer 250 may be disposed on the first refractive layer 240 via the operations described above with reference to FIGS. 7E and 7F.

In an embodiment, a display apparatus may include overlapping lenses (or, refractive layers) disposed in the bank layer. The display apparatus may have enhanced quality by refracting light emitted from the light-emitting diode to a predetermined angle.

In an embodiment, an electronic device may include the display apparatus described above, and may equally provide the effects provided by the display apparatus.

In an embodiment, a method of manufacturing a display apparatus may include disposing a solution in the bank layer, drying the solution, and hardening the solution. The method of manufacturing a display apparatus may include drying the solution to induce a coffee-ring effect to facilitate forming of a concave shape of the lens (or refractive layer). The manufacturing process of the display apparatus may be simplified, thereby reducing manufacturing time and cost.

While embodiments are described with reference to the drawing figures, it will be understood by one of ordinary skill in the art that various equivalents in form and details may be made therein. Therefore, the scope of the disclosure should be defined by the spirit and scope of the following claims.

What is claimed is:

1. A display apparatus comprising:
a substrate;
a light-emitting diode disposed on the substrate and comprising an emission layer;
a bank layer disposed on the substrate and defining an opening overlapping the emission layer of the light-emitting diode;
a first refractive layer disposed in the opening of the bank layer, the first refractive layer comprising:
a concave top surface; and
a second refractive layer disposed on the first refractive layer, the second refractive layer comprising:
a convex bottom surface; and
a convex top surface.

2. The display apparatus of claim 1, wherein
the second refractive layer is disposed in the opening of the bank layer.

3. The display apparatus of claim 1, wherein
the second refractive layer at least covers a partial portion of a top surface of the bank layer.

4. The display apparatus of claim 1, wherein
the emission layer of the light-emitting diode is disposed in the opening of the bank layer.

5. The display apparatus of claim 4, wherein
the light-emitting diode comprises a pixel electrode disposed under the emission layer and an opposite electrode disposed on the emission layer,
and the first refractive layer is disposed on the opposite electrode.

6. The display apparatus of claim 1, further comprising
an encapsulation layer covering an entirety of the light-emitting diode,
wherein the bank layer, the first refractive layer, and the second refractive layer are disposed on the encapsulation layer.

7. The display apparatus of claim 6, further comprising
a color filter disposed in the opening of the bank layer,
wherein the first refractive layer is disposed on the color filter.

8. The display apparatus of claim 1, wherein
a refractive index of the first refractive layer is less than a refractive index of the second refractive layer.

9. The display apparatus of claim 1, wherein
the concave top surface of the first refractive layer and the convex bottom surface of the second refractive layer match each other.

10. An electronic device comprising:
a display apparatus comprising:
a substrate;
a light-emitting diode disposed on the substrate and comprising an emission layer;
a bank layer disposed on the substrate and defining an opening overlapping the emission layer of the light-emitting diode;
a first refractive layer disposed in the opening of the bank layer, the first refractive layer comprising:
a concave top surface; and
a second refractive layer disposed on the first refractive layer, the second refractive layer comprising:
a convex bottom surface; and
a convex top surface; and
a housing receiving the display apparatus.

11. A method of manufacturing a display apparatus, the method comprising:
disposing a bank layer defining an opening on a substrate;
disposing a first refractive layer with a concave top surface in the opening of the bank layer; and
disposing a second refractive layer with a convex bottom surface and a convex top surface on the first refractive layer;
wherein the disposing the first refractive layer comprises:
disposing a first solution in the opening of the bank layer;
drying the first solution; and
hardening a dried first solution.

12. The method of claim 11, wherein
the drying the first solution is performed in a vapor pressure of a solvent of the first solution.

13. The method of claim 11, wherein
the disposing the second refractive layer comprises:
disposing a second solution on the first refractive layer; and
hardening the second solution.

14. The method of claim 13, wherein
the disposing the second solution is performed after the hardening the first solution.

15. The method of claim 11, further comprising:
disposing a pixel electrode under the bank layer to overlap the opening of the bank layer;
disposing an emission layer in the opening of the bank layer; and
disposing an opposite electrode on the bank layer.

16. The method of claim 15, wherein
the first refractive layer is disposed on the opposite electrode.

17. The method of claim 11, further comprising:
disposing, on the substrate, a light-emitting diode comprising a pixel electrode, an emission layer, and an opposite electrode; and
disposing an encapsulation layer to cover an entirety of the light-emitting diode,
wherein the bank layer is disposed on the encapsulation layer.

18. The method of claim 17, further comprising
disposing a color filter in the opening of the bank layer,
wherein the first refractive layer is disposed on the color filter.

19. The method of claim 11, wherein
a refractive index of the first refractive layer is less than a refractive index of the second refractive layer.

20. The method of claim 11, wherein
the concave top surface of the first refractive layer and the convex bottom surface of the second refractive layer match each other.
